(19) United States
(12) Patent Application Publication
(10) Pub. No.: US 2013/0069129 A1
(43) Pub. Date: Mar. 21, 2013

(54) COMPOUND SEMICONDUCTOR DEVICE AND METHOD OF MANUFACTURING THE SAME

(71) Applicants: Kozo MAKIYAMA, Kawasaki (JP); Toshihide Kikkawa, Machida (JP)

(72) Inventors: Kozo MAKIYAMA, Kawasaki (JP); Toshihide Kikkawa, Machida (JP)

(73) Assignee: FUJITSU LIMITED, Kawasaki-shi (JP)

(21) Appl. No.: 13/611,111

(22) Filed: Sep. 12, 2012

(30) Foreign Application Priority Data
Sep. 21, 2011 (JP) 2011-206553

(51) Int. Cl. H01L 29/78; H01L 21/283

(52) U.S. Cl. 257/288; 438/585; 257/E29.255; 257/E21.19

(57) ABSTRACT

Disclosed is a compound semiconductor device in which a first protective film, which is homogeneous and composed of a single material (SiN, in this case) and therefore has a uniform dielectric constant, continuously covers a compound semiconductor layer; an oxygen-containing protective component, which is a second protective film composed of an oxide film, is formed so as to cover one edge portion of an opening formed in the first protective film; and a gate electrode is formed so as to fill the opening and so as to embrace therein the second protective film.

### CROSS-REFERENCE TO RELATED APPLICATION

This application is based upon and claims the benefit of priority of the prior Japanese Patent Application No. 2011-206553, filed on Sep. 21, 2011, the entire contents of which are incorporated herein by reference.

### FIELD

The embodiments discussed herein are related to a compound semiconductor device and a method of manufacturing the same.

### BACKGROUND

Nitride-based semiconductor devices, featured by their high saturation electron velocity and wide band gap, have been vigorously developed in expectation of semiconductor devices for high-voltage and high-output use. Among the nitride-based semiconductor devices, field effect transistor, in particular high electron mobility transistor (HEMT), has been investigated in numerous reports. In particular, AlGaN/GaN-based HEMT, using GaN for the channel layer and AlGaN for the donor layer has attracted public attention. In the AlGaN/GaN-based HEMT, strain generates in AlGaN due to difference in lattice constants between GaN and AlGaN. By contributions of Piezo polarization induced by the strain and spontaneous polarization of AlGaN, a high density two-dimensional electron gas (2DEG) is obtained, and thereby the high-voltage and high-output devices may be implemented.

Patent Literature 1: Japanese Laid-Open Patent Publication No. 2010-251456

Patent Literature 2: Japanese National Publication of International Patent Application No. 2009-524242

For larger output of the nitride-based semiconductor devices for high-output and high-frequency use, such as AlGaN/GaN-based HEMT, it is necessary to elevate the operational voltage. Increase in the operational voltage aimed at larger output, however, increases electric field strength around the gate electrode, and thereby induces degradation of device characteristics (chemical and/or physical changes). In order to improve reliability of the nitride-based semiconductor devices for high output use, it is therefore essential to suppress the degradation of device characteristics due to the strong electric field possibly induced around the gate electrode.

### SUMMARY

According to one aspect of the embodiments, there is provided a compound semiconductor device which includes a compound semiconductor layer; an insulating film which is composed of a single material and formed as a homogeneous film which covers the compound semiconductor layer, and has an opening formed therein; and

a gate which is formed over the compound semiconductor layer so as to fill the opening,

the compound semiconductor device further having an oxygen-containing protective component formed at one edge portion of the opening.

According to another aspect of the embodiments, there is provided a method of manufacturing a compound semiconductor device which includes:

forming an insulating film which is composed of a single material and formed as a homogeneous film which covers the compound semiconductor layer, and has an opening formed therein; and

forming an oxygen-containing protective component at one edge portion of the opening formed in the insulating film; and

forming a gate over the compound semiconductor layer so as to fill the opening.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A to 1C, 2A to 2C, 3A and 3B, 4A and 4B are schematic cross sectional views illustrating step-by-step a method of manufacturing a Schottky AlGaN/GaN-based HEMT of a first embodiment;

FIG. 5 is a schematic cross sectional view illustrating the Schottky AlGaN/GaN-based HEMT of the first embodiment.

FIG. 6 is a schematic cross sectional view illustrating a conventional AlGaN/GaN-based HEMT for comparison to the first embodiment;

FIG. 7 is a characteristic chart illustrating changes in gate leakage current in the AlGaN/GaN-based HEMT of the first embodiment, under electric conduction at high temperature;

FIGS. 8A to 8C are schematic cross sectional views illustrating essential steps of manufacturing a Schottky AlGaN/GaN-based HEMT according to a modified example of the first embodiment;

FIGS. 9A to 9C, 10A and 10B are schematic cross sectional views illustrating essential steps of manufacturing a Schottky AlGaN/GaN-based HEMT according to a second embodiment;

FIG. 11 is a connection diagram illustrating an overall configuration of a power supply of a third embodiment; and

FIG. 12 is a connection diagram illustrating an overall configuration of a high-frequency amplifier of a fourth embodiment.

### DESCRIPTION OF EMBODIMENTS

Various embodiments will be detailed below, referring to the attached drawings. In the various embodiments below, configurations of the compound semiconductor device will be explained, together with methods of manufacturing the same.

Note that, in the drawings referred to below, the constituents are not always depicted with exact size and thickness, for convenience of illustration.

### First Embodiment

This embodiment discloses a Schottky AlGaN/GaN-based HEMT as the compound semiconductor device.

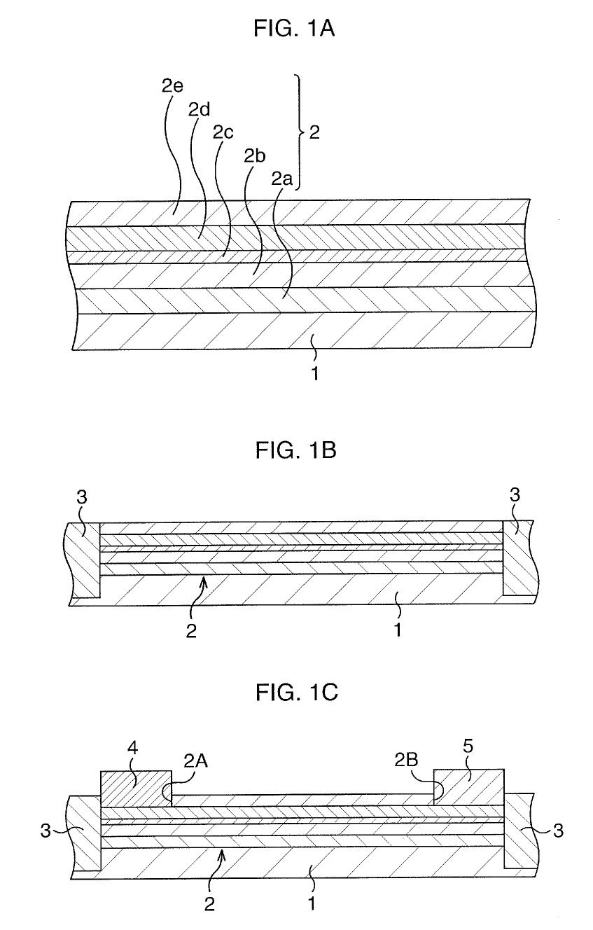

FIG. 1A to FIG. 4B are schematic cross sectional views illustrating step-by-step a method of manufacturing the Schottky AlGaN/GaN-based HEMT of the first embodiment.

First, as illustrated in FIG. 1A, typically on a semi-insulating SiC substrate 1 which is used as a growth substrate, a compound semiconductor layer 2 is formed. The compound semiconductor layer 2 has a stacked structure of compound semiconductor layers, and is composed of a buffer layer 2a, a channel layer 2b, an intermediate layer 2c, a donor layer 2d, and a capping layer 2e. In the AlGaN/GaN-based HEMT, a two-dimensional electron gas (2DEG) is formed in the channel layer 2b in the vicinity of the interface with the donor layer 2d (more exactly, with the intermediate layer 2c).

In further detail, on the SiC substrate 1, the individual compound semiconductors described below are grown typically by metal organic vapor phase epitaxy (MOVPE). In place of the MOVPE process, also molecular beam epitaxy (MBE) is adoptable.

On the SiC substrate 1, the buffer layer 2a, the channel layer 2b, the intermediate layer 2c, the donor layer 2d, and the capping layer 2e are formed in a stacked manner, by sequentially depositing AlN, i(intentionally undoped)-GaN, i-AlGaN, n-AlGaN, and n-GaN. In the process of growth of AlN, GaN, AlGaN, and GaN, a mixed gas of trimethylaluminum gas, trimethylgallium gas and ammonia gas is used as a source gas. On/off of supply and flow rates of trimethylaluminum gas as an Al source and trimethylgallium gas as a Ga source are appropriately set, depending on composition of the compound semiconductor layers to be grown. Flow rate of ammonia gas, which is common to all compound semiconductor layers, is set to approximately 100 ccm to 10 LM. Growth pressure is adjusted to approximately 50 Torr to 300 Torr, and growth temperature is adjusted to approximately 1,000° C. to 1,200° C., for example.

In the process of growing of GaN and AlGaN aimed at obtaining n-type compound semiconductor layers, Si for example is doped into GaN and AlGaN typically by adding SiH₄ gas, which contains Si as an n-type impurity, to the source gas at a predetermined flow rate. Dose of Si is adjusted to approximately 1×10¹⁸/cm³ to 1×10²⁰/cm³, and typically to 5×10¹⁸/cm³ or around.

The buffer layer 2a formed herein is approximately 0.1 μm thick, the channel layer 2b is approximately 3 μm thick, the intermediate layer 2c is approximately 5 nm thick, the donor layer 2d is approximately 20 nm thick and has an Al ratio of 0.2 to 0.3 or around, and the capping layer 2e is approximately 10 nm thick.

Next, as illustrated in FIG. 1B, an element isolation structure 3 is formed.

In further detail, argon (Ar) is implanted into the compound semiconductor layer 2 in a region thereof to be converted into an element isolation region. As a consequence, the element isolation structure 3 is formed so as to extend through the compound semiconductor layer 2, and to partially remove the surficial portion of the SiC substrate 1. By the element isolation structure 3, an active region is determined on the compound semiconductor layer 2.

Alternatively, the element isolation may be established by STI (shallow trench isolation) in place of the implantation described in the above.

Next, as illustrated in FIG. 1C, a source electrode 4 and a drain electrode 5 are formed. In further detail, first, electrode-forming trenches 2A, 2B are formed in the capping layer 2e, in regions in the plan view of the compound semiconductor layer 2 where a source electrode and a drain electrode will be formed layer.

In this process, a resist mask which has openings at the regions where the source electrode and the drain electrode will be formed later, is formed on the surface of the compound semiconductor layer 2. The capping layer 2e is then removed in the openings of the resist mask by dry etching. The electrode-forming trenches 2A, 2B are thus formed. An inert gas such as Ar, and a chlorine-containing gas such as Cl₂ are used as an etching gas in the dry etching. Alternatively, the electrode-forming trenches may be formed by dry etching, so as to penetrate the capping layer 2e deeply enough to partially remove the surficial portion of the donor layer 2d.

An electrode material adoptable herein is Ti/Al, for example. In the process of forming the electrodes, vacuum evaporation process may be combined with a double-layered resist having overhang geometry suitable for the liftoff process. More specifically, a resist material is coated over the compound semiconductor layer 2, and is then patterned to form the resist mask having the electrode-forming trenches 2A, 2B. Ti/Al layers are then deposited over the entire surface. The Ti layer deposited herein is approximately 20 nm thick, and the Al layer is approximately 200 nm thick. Then by the liftoff process, upper portions of the Ti/Al layers deposited over the resist mask having the overhang structure are removed together with the resist mask. Thereafter, the SiC substrate 1 is annealed typically in a nitrogen atmosphere at 550° C. or around, so as to establish ohmic contact between the residual lower portions of the Ti/Al layers and the donor layer 2d. By the procedures, the source electrode 4 and the drain electrode 5 are formed by the residual lower portions of the Ti/Al layers so as to fill the electrode-forming trenches 2A, 2B.

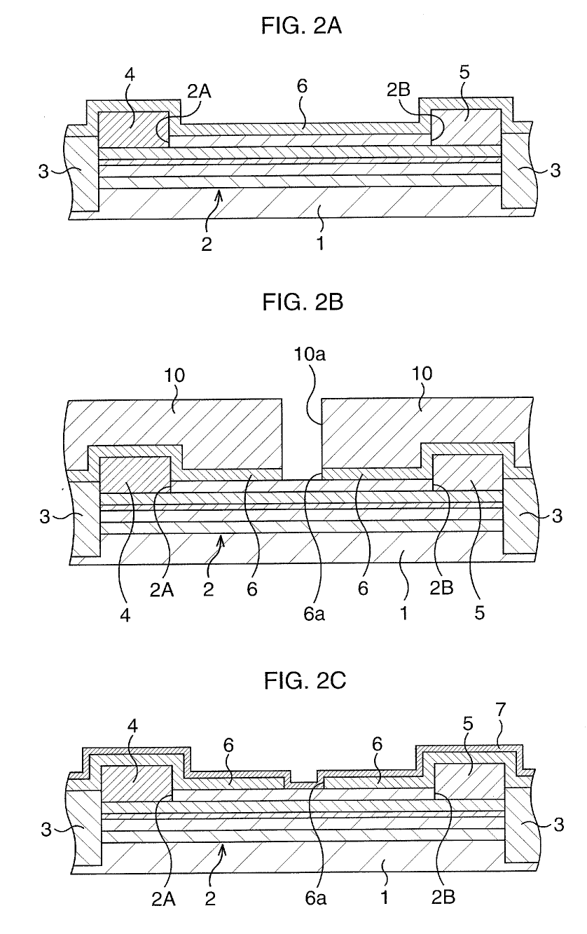

Next, as illustrated in FIG. 2A, a first protective film 6 is formed.

In further detail, an insulating material, exemplified by silicon nitride (SiN) is deposited over the entire surface of the compound semiconductor layer 2, typically by plasma-assisted CVD. In this way, the first protective film 6 of approximately 50 nm thick is formed. The first protective film 6 which covers the compound semiconductor layer 2 herein is composed of a homogeneous, single material (SiN, in this case).

Alternatively, alumina (Al₂O₃), silicon oxide (SiO₂), silicon oxynitride (SiON) and so forth may be used as materials for composing the first protective film, in place of SiN.

For the case where SiO₂ is used as a material for composing the first protective film, the bond of SiO₂ is broken in the process of dry etching adopted to form the openings in the first protective film, and thereby dangling bond increases at the edges of the openings, although the initial content of dangling bond of SiO₂ is not so large. In this embodiment, the edge of the opening will be protected by a second protective film, as described later.

Next, as illustrated in FIG. 2B, an opening 6a is formed in the first protective film 6.

In further detail, first, a resist is coated over the entire surface of the first protective film 6. The resist is then exposed to UV light according to an opening pattern of 600 nm wide, and is then developed. A resist mask 10 with an opening 10a formed therein is formed in this way.

Next, using the resist mask 10, the first protective film 6 is etched by dry etching using SF₆ as an etching gas. By the process, the first protective film 6 is etched in the region exposed in the opening 10a, and thereby the opening 6a is formed in the first protective film 6.

The resist mask 10 is then removed by oxygen plasma-assisted ashing, or a wet process using a chemical solution.

Next, as illustrated in FIG. 2C, an oxide film 7 is formed.

In further detail, a predetermined oxide is deposited on the first protective film 6. The oxide is preferably silicon oxide (SiO₂), silicon oxynitride (SiON), carbon-containing silicon oxide (SiOC) such as SOG, alumina (Al₂O₃), and hafnium oxide (HfO₂). In this embodiment, SiO₂ is used for example. More specifically, an electron beam sensitive SOG (negative type) is coated by spin coating over the entire surface of the first protective film 6, including the inside of the opening 6a. The oxide film 7 is thus formed.

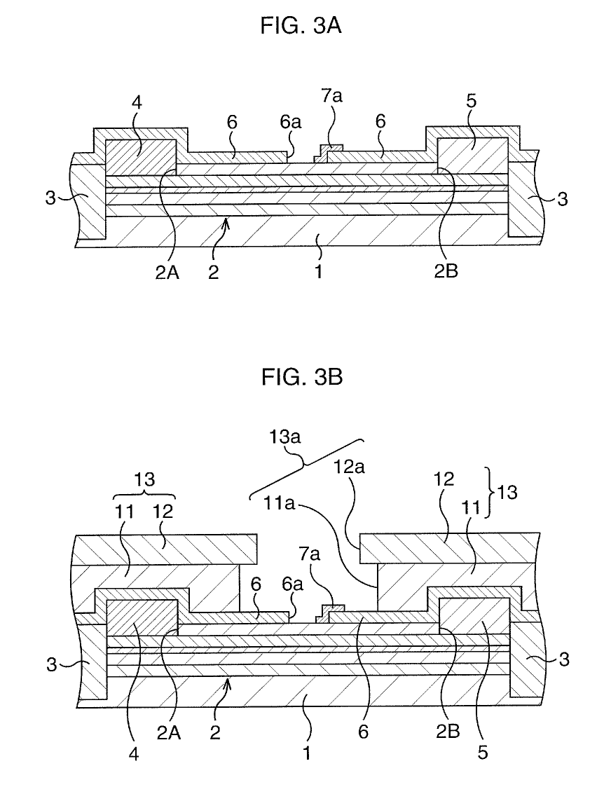

Next, as illustrated in FIG. 3A, a second protective film 7a is formed.

In further detail, the oxide film 7 is irradiated with electron beam selectively in a region which falls on one edge portion of the opening 6a, by electron beam lithography. In this example, a predetermined dose of electron beam is irradiated in a region ranging from a position on the oxide film approximately 100 nm set back away from the edge on the drain forming side of the opening 6a towards the drain forming side, up to a position in the opening 6a approximately 50 nm ahead of the edge. The oxide film 7 is then developed and cured. As a consequence, the oxide film 7 remains only in the above-described region, and thereby the second protective film 7a is formed. The second protective film 7a is formed so as to extend from the surface of the protective film 6, covering the side face of the opening 6a, to overlap a part of the bottom surface of the opening 6a where the surface of the compound semiconductor layer 2 exposes.

In place of relying upon the electron beam lithography, the second protective film 7a may formed alternatively by forming a resist mask on the oxide film 7 so as to mask only the above-described region, and by etching the oxide film 7 by dry etching using the resist mask.

Next, as illustrated in FIG. 3B, a resist mask 13 used for patterning of the gate is formed.

In further detail, first, a lower resist layer (for example, PMGI (trade name) from MicroChem Corp., U.S.A) and an upper resist layer 12 (for example, PFI32-A8 (trade name) from Sumitomo Chemical Co. Ltd.) are respectively coated by spin coating over the entire surface. An opening 12a of approximately 1.5 μm in diameter is formed in the upper resist layer 12 by UV lithography. Next, the lower resist layer 11 is etched by wet etching using an alkaline developer solution, while using the upper resist layer 12 as a mask, to thereby form an opening 11a in the lower resist layer 11. As a consequence, a resist mask 13 which is composed of the lower resist layer 11 with the opening 11a formed therein, and the upper resist layer 12 with the opening 12a formed therein, is formed. An opening formed in the resist mask 13, composed of the opening 11a and the opening 12a communicating with each other, is now denoted as an opening 13a.

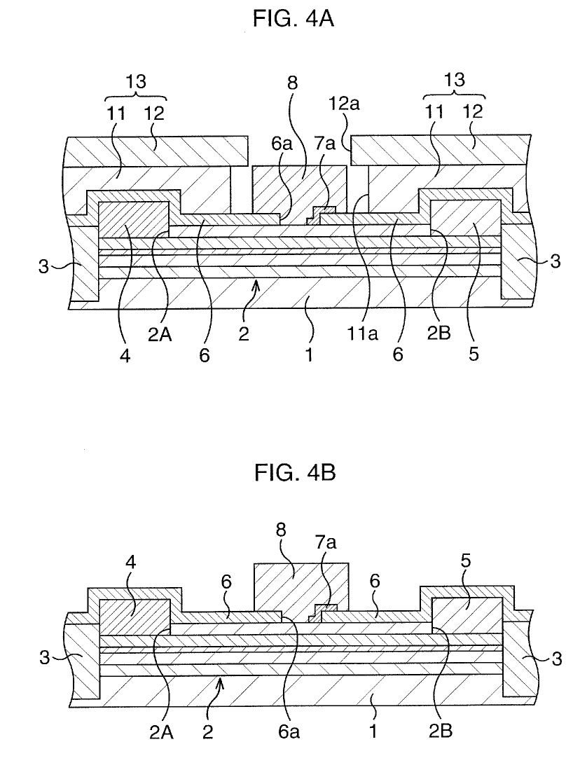

Next, as illustrated in FIG. 4A, a gate electrode 8 is formed.

In further detail, a gate metal (Ni/Au; where Ni is approximately 10 nm thick, and Au is approximately 300 nm thick) is formed by vacuum evaporation onto the entire surface including inside of the opening 13a, while using the resist mask 13 as a mask. In this way, there is formed the gate electrode 8, which is composed of the gate metal formed so as to fill the opening 6a in the first protective film 6, and establishes Schottky contact with the surface of the compound semiconductor layer 2.

Next, as illustrated in FIG. 4B, the resist mask 13 is removed.

In further detail, the SiC substrate 1 is immersed into N-methyl-pyrrolidinone warmed at 80° C., and the resist mask 13 and unnecessary portions of the gate metal deposited thereon are removed by the liftoff process. The gate electrode 8 is formed so as to establish, in the lower portion thereof, Schottky contact with the surface of the compound semiconductor layer 2 in the opening 6a, and so as to be widened in the upper portion thereof from the width of the opening 6a. The second protective film 7a is located under the upper portion of the gate electrode 8, and covered by the gate electrode 8 so as to be embraced therein.

Thereafter, the process is followed typically by electrical connection of the source electrode 4, the drain electrode 5, and the gate electrode 8, and thereby the Schottky AlGaN/GaN-based HEMT is completed.

Next, effects of the Schottky AlGaN/GaN-based HEMT of this embodiment will be explained below, in comparison with a comparative example.

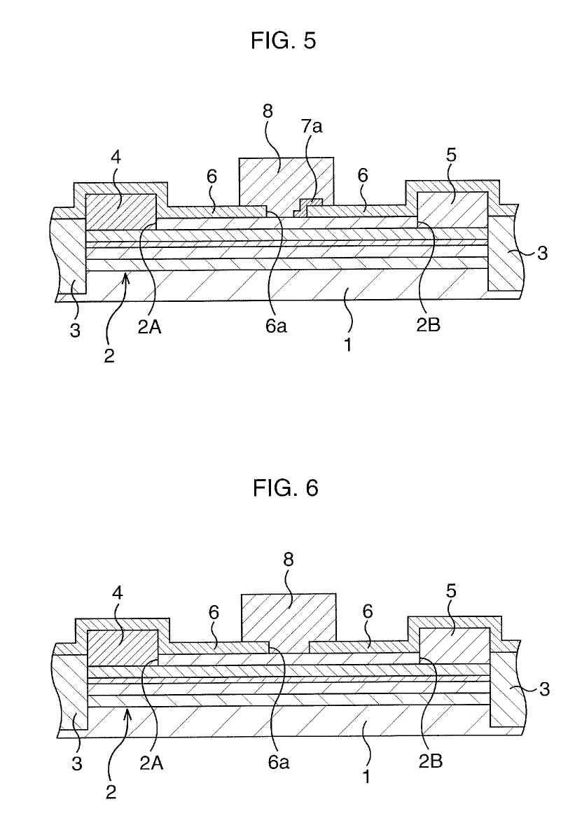

FIG. 5 is a schematic cross sectional view illustrating the Schottky AlGaN/GaN-based HEMT of the first embodiment, which is identical to FIG. 4B. FIG. 6 is a schematic cross sectional view illustrating a conventional AlGaN/GaN-based HEMT, for comparison to this embodiment.

In the AlGaN/GaN-based HEMT of this embodiment, as illustrated in FIG. 5, the first protective film 6 covers the compound semiconductor layer 2. The second protective film 7a is formed at one edge portion of the opening 6a formed in the first protective film 6, and the gate electrode 8 is formed so as to fill the opening 6a and so as to embrace the second protective film 7a.

On the other hand, in the AlGaN/GaN-based HEMT of the comparative example having no second protective film 7a, as illustrated in FIG. 6, the gate electrode 8 is brought into direct contact with the side wall of the opening 6a formed in the first protective film 6. The first protective film 6 is often formed by plasma-assisted CVD, and the insulating film formed by the process is generally known to have a large number of lone pairs (dangling bonds). The dangling bonds (including hydrogen bond-forming groups) are very effective in view of suppressing current collapse specific to the GaN-HEMT. However, if such structure having the insulating film and the gate electrode brought into direct contact is placed in a strong electric field, the incompletely terminated state due to abundance of the dangling bonds [the state is represented by “dangling bonds (including hydrogen bond-forming groups)”, hereinafter] is likely to proceed reaction with the metal in the gate electrode, to thereby give silicide. The silicide is supposed to serve as a leakage path of the gate current, if it is brought into contact with the compound semiconductor layer 2. It is also supposed that, at the site of silicidation, also a reaction between the metal diffused from the gate and the compound semiconductor per se is likely to proceed. In short, due to the presence of a large amount of dangling bonds at one edge portion of the opening 6a formed in the first protective film 6, a predetermined reaction may proceed among three participants, that is, the compound semiconductor layer 2, the first protective film 6 and the gate electrode 8, to thereby form the current leakage path, and this may induce degradation of device characteristics (chemical and/or physical changes).

In contrast, in this embodiment, the first protective film 6 covers the compound semiconductor layer 2. More specifically, the first protective film 6, which is homogeneous and composed of a single material (SiN, in this case) and therefore has a uniform dielectric constant, continuously covers the compound semiconductor layer 2, except for the region where the gate electrode 8 is brought into Schottky contact therewith. In this configuration, there is no discontinuity of the dielectric constant in the first protective film 6, so that concentration of electric field due to the discontinuity is no longer anticipated.

On one edge portion of the opening 6a formed in the first protective film 6, the protective component is locally formed. In the illustrated example, the second protective film 7a, which is composed of an insulating material containing oxygen and only a less amount of dangling bond (including hydrogen bond-forming group), is formed so as to cover one edge portion on the drain electrode side of the opening 6a. The one edge portion on the drain electrode 5 side of the opening 6a is a portion most likely to cause concentration of electric field, since there is a difference in height between the first protective film 6 and the compound semiconductor layer 2, and since the portion is close to the drain electrode 5. In this embodiment, a region containing the one edge portion is covered with the second protective film 7a containing only a less amount of dangling bond. By the configuration, the first protective film 6 containing a large amount of dangling bond and is therefore highly reactive may be prevented from being brought into contact with the gate electrode 8, and thereby reaction such as silicidation is prevented. In addition, oxygen contained in the second protective film 7a reacts for example with Ni, which is a constitutive element of the gate electrode 8, to produce a passivation product which exhibits a stronger effect of preventing silicidation. Presence of the second protective film 7a is also advantageous since the gate electrode 8 is prevented from reacting directly with the compound semiconductor layer 2.

As described in the above, according to this embodiment, reaction among three participants, that is, the compound semiconductor layer 2, the first protective film 6 and the gate electrode 8, may be prevented by the second protective film 7a, and thereby the device characteristics may be prevented from degrading, while successfully ensuring, by virtue of the first protective film 6, an effect of preventing concentration of electric field, which would otherwise be induced by discontinuity of dielectric constant.

Points of concentration of electric field may be distributed into arbitrary sites, by appropriately controlling arrangement of the second protective film 7a, typically by controlling the edge position thereof on the first insulating film 6. A part of points of concentration of electric field may be brought apart from the gate electrode 8 by bringing the edge position apart from the gate electrode 8, and thereby degradation of device characteristics may be prevented in a more thorough manner.

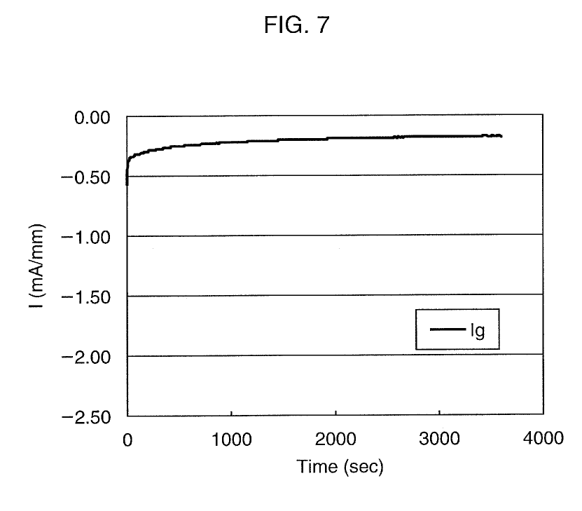

Changes in the amount of gate leakage current in the AlGaN/GaN-based HEMT of this embodiment, under electric conduction at high temperature were investigated. Result was shown in FIG. 7.

As is known from FIG. 7, it was confirmed that, in the AlGaN/GaN-based HEMT of this embodiment, the gate leakage current was suppressed from increasing over a long duration of time under electric conduction at the pinch-off voltage at 200° C. The result indicates that the AlGaN/GaN-based HEMT of this embodiment is excellent in the device characteristics, and is proven to be highly reliable.

As described in the above, according to this embodiment, there is obtained a highly reliable AlGaN/GaN-based HEMT featured by high voltage resistance and large output, and is thoroughly suppressed in degradation of device characteristics (chemical and/or physical changes), even under elevated operational voltage.

### MODIFIED EXAMPLE

A modified example of the Schottky AlGaN/GaN-based HEMT of the first embodiment will be explained below. The modified example is different from the first embodiment, in the geometry of the second protective film. Note that all constituents similar to those in the AlGaN/GaN-based HEMT of the first embodiment will be given the same reference numerals, in order to avoid repetitive explanation.

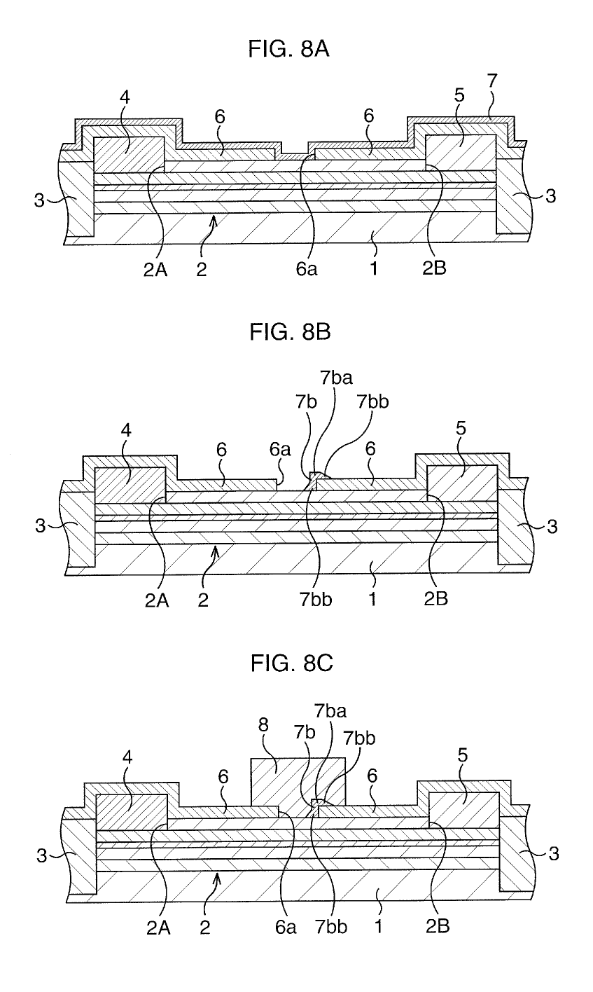

FIGS. 8A to 8C are schematic cross sectional views illustrating essential steps of manufacturing a Schottky AlGaN/GaN-based HEMT according to the modified example of the first embodiment.

First, conforming to the processes previously illustrated in FIG. 1A to FIG. 2C in the first embodiment, the oxide film 7 is formed over the first protective film 6. The state of finish of the process is illustrated in FIG. 8A.

Next, as illustrated in FIG. 8B, the second protective film 7b is formed.

In further detail, electron beam is irradiated by the electron beam lithography onto the oxide film 7, particularly in a portion which falls on one edge portion of the opening 6a. In this process, a predetermined dose of electron beam is irradiated in a region ranging from a position on the oxide film 7 approximately 100 nm set back away from the edge on the drain forming side of the opening 6a towards the drain forming side, up to a position in the opening 6a approximately 50 nm ahead of the edge. The dose of electron beam herein is adjusted so as to be kept constant at around the center of the region, and so as to decrease from the above-described constant value towards the near-the-edge region. The oxide film 7 is then developed and cured. As a consequence, the oxide film 7 remains only in the above-described region, and thereby the second protective film 7b is formed. As seen in FIG. 8B, the second protective film 7b has a tapered cross section such as having a constant thickness in a center region 7ba thereof, and gradually thinned towards the near-the-edge region 7bb.

In place of relying upon the electron beam lithography, a resist mask may be formed on the oxide film 7 so as to expose only the above-described region, and the oxide film 7 is then etched by wet etching using the resist mask. By the wet etching, the second protective film 7b is formed so as to be gradually thinned towards the end of the near-the-edge region 7bb.

Next, the processes illustrated in FIG. 3B to FIG. 4B in the first embodiment are implemented. FIG. 8C illustrate a state identical to FIG. 4B.

The processes are followed by electrical connection of the source electrode 4, the drain electrode 5 and the gate electrode 8, to thereby complete the Schottky AlGaN/GaN-based HEMT.

According to this modified example, similarly to the first embodiment, reaction among three participants, that is, the compound semiconductor layer 2, the first protective film 6 and the gate electrode 8, may be prevented, and thereby the device characteristics may be prevented from degrading, while successfully ensuring, by virtue of the first protective film 6, an effect of preventing concentration of electric field, which would otherwise be induced by discontinuity of dielectric constant.

In addition in this modified example, the second protective film 7b is given a geometry featured by a constant thickness in the center region 7ba and thinned towards the edge in the near-the-edge region 7bb.

The second protective film 7a in this embodiment (first embodiment) showed a difference in height at the edge thereof relative to the first protective film 6, and thereby the electric field may increase at the edges (in particular, at the edge on the drain electrode 5 side). In contrast, the second protective film 7b of this modified example is thinned towards the end of the near-the-edge region 7bb so as to clear the difference in height. Accordingly, concentration of the electric field at the edge of the second protective film 7b may be moderated, so that the first protective film 6 and the second protective film 7b, and the compound semiconductor layer 2 may be prevented from being denatured in the vicinity of the gate electrode 8, and thereby the device characteristics may be prevented from degrading in a more complete manner.

As described in the above, according to this modified example, there is obtained a highly reliable AlGaN/GaN-based HEMT featured by high voltage resistance and large output, and is more thoroughly suppressed in degradation of device characteristics (chemical and/or physical changes), even under elevated operational voltage.

### Second Embodiment

A Schottky AlGaN/GaN-based HEMT of a second embodiment will be explained below. This embodiment is different from the first embodiment in the mode of protective component which corresponds to the second protective film in the first embodiment. Note that all constituents similar to those in the AlGaN/GaN-based HEMT of the first embodiment will be given the same reference numerals, in order to avoid repetitive explanation.

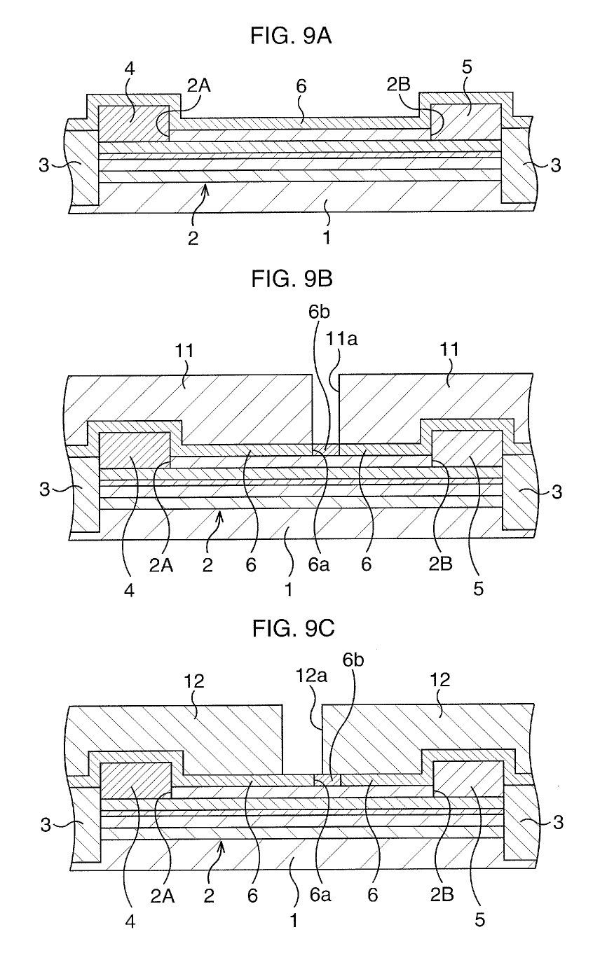

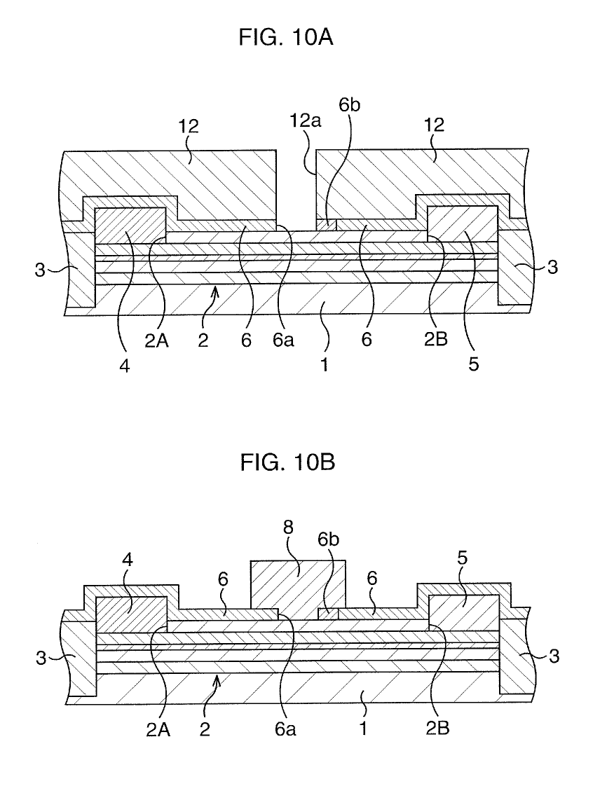

FIGS. 9A to 9C, 10A and 10B are schematic cross sectional views illustrating essential steps of manufacturing a Schottky AlGaN/GaN-based HEMT according to the second embodiment.

First, conforming to the processes previously illustrated in FIG. 1A to FIG. 2A in the first embodiment, the first protective film 6 is formed over the entire surface of the compound semiconductor layer 2. The state of finish of the process is illustrated in FIG. 9A.

Next, as illustrated in FIG. 9B, a protective region 6b is formed in the first protective film 6.

In further detail, first, a resist is coated over the entire surface of the first protective film 6. The resist is irradiated by electron beam by the electron beam lithography, typically in a predetermined region of 200 nm wide positioned closer to the drain electrode 5, between the source electrode 4 and the drain electrode 5, and then developed. In this way, a resist mask 11 having therein an opening 11a is formed.

Next, oxygen is implanted into the first protective film 6 using the resist mask 11. Oxygen herein is implanted into a predetermined region of the first protective film 6 which exposes in the opening 11a. Oxygen herein is implanted only into the surficial portion of the predetermined region. More specifically, oxygen is implanted under a condition which allows oxygen to distribute only in the surficial portion of the predetermined region as viewed in the depth-wise direction, rather than allowing oxygen to distribute over the entire depth (adjustment of ion acceleration energy). Accordingly, the surficial portion of the predetermined region turns into oxygen-rich, and thereby the protective region 6b is formed. The first protective film 6 is not denatured in the region other than the surficial portion in the predetermined region even after the protective region 6b is formed, and is kept in a homogeneous state composed of a single material (SiN in this case).

The resist mask 11 is removed by oxygen plasma-assisted ashing, or a wet process using a chemical solution.

Next, as illustrated in FIG. 9C, a resist mask 12 is formed.

In further detail, a resist is coated over the entire surface of the first protective film 6. The resist is subjected to UV lithography for forming a 600 nm-wide opening, and is then developed. The resist mask 12 having therein the opening 12a is thus formed. In the opening 12a, there is exposed a part of the surface of the first protective film 6, together with a part of the protective region 6b on the source electrode 4 side thereof.

Next, as illustrated in FIG. 10A, the opening 6a is formed in the first protective film 6.

In further detail, the first protective film 6 is etched by dry etching using SF₆ as an etching gas and the resist mask 12. By the process, a portion of the first protective film 6 exposed in the opening 12a is etched, and thereby the opening 6a is formed in the first protective film 6. As a result of formation of the opening 6a, the protective region 6b remains over a region ranging from the one edge, on the drain electrode 5 side, of the opening 6a up to the position approximately 100 nm set back from the one edge towards the drain electrode 5.

The resist mask 12 is removed by oxygen plasma-assisted ashing, or a wet process using a chemical solution.

Next, the processes illustrated in FIG. 3B to FIG. 4B of the first embodiment are implemented. FIG. 10B illustrates a state identical to FIG. 4B.

The processes are followed by electrical connection of the source electrode 4, the drain electrode 5 and the gate electrode 8, to thereby complete the Schottky AlGaN/GaN-based HEMT.

In the AlGaN/GaN-based HEMT of this embodiment, first the first protective film 6 covers the compound semiconductor layer 2. More specifically, the first protective film, which is homogeneous and composed of a single material (SiN, in this case) and therefore has a uniform dielectric constant, continuously covers the compound semiconductor layer 2, except for the region where the gate electrode 8 is brought into Schottky contact therewith. In this configuration, there is no discontinuity of the dielectric constant in the first protective film 6, so that concentration of electric field due to the discontinuity is no longer anticipated.

On one edge portion of the opening 6a formed in the first protective film 6, the protective component is locally formed. In the illustrated example, the protective region 6b, which is implanted with oxygen and therefore has only a less amount of dangling bond (including hydrogen bond-forming group), is formed in the surficial portion in one edge portion on the drain electrode 5 side of the opening 6a formed in the first protective film. The one edge portion on the drain electrode 5 side of the opening 6a is a portion most likely to cause concentration of electric field, since there is a difference in height between the first protective film 6 and the compound semiconductor layer 2, and since the portion is close to the drain electrode 5. In this embodiment, a region containing the one edge portion of the first protective film 6 is denatured by oxygen implantation, to thereby form the protective region 6b containing only a less amount of dangling bond. By the configuration, the first protective film 6 containing a large amount of dangling bond and is therefore highly reactive may be prevented from being brought into contact with the gate electrode 8, and thereby reaction such as silicidation is prevented. In addition, oxygen contained in the protective region 6b reacts for example with Ni, which is a constitutive element of the gate electrode 8, to produce a passivation product which exhibits a stronger effect of preventing silicidation. Presence of the protective region 6b is also advantageous since the gate electrode 8 is prevented from reacting directly with the compound semiconductor layer 2.

In short, according to the this embodiment, reaction among three participants, that is, the compound semiconductor layer 2, the first protective film 6 and the gate electrode 8, may be prevented by the protective region 6b, and thereby the device characteristics may be prevented from degrading, while successfully ensuring, by virtue of the first protective film 6, an effect of preventing concentration of electric field, which would otherwise be induced by discontinuity of dielectric constant.

Since the protective region 6b is a locally denatured portion of the first protective film 6 formed by oxygen implantation, the first protective film 6 will have no difference in height in the plane thereof, even in the vicinity of the boundary with the protective region 6b. Accordingly, the electric field is prevented from concentrating in the vicinity of the boundary, and thereby the device characteristics may be prevented from degrading in a more thorough manner.

As described in the above, according to this embodiment, there is obtained a highly reliable AlGaN/GaN-based HEMT featured by high voltage resistance and large output, and is thoroughly suppressed in degradation of device characteristics (chemical and/or physical changes), even under elevated operational voltage.

### Third Embodiment

This embodiment discloses a power supply equipped with any one type of AlGaN/GaN-based HEMT selected from those in the first embodiment and the modified example thereof, and the second embodiment.

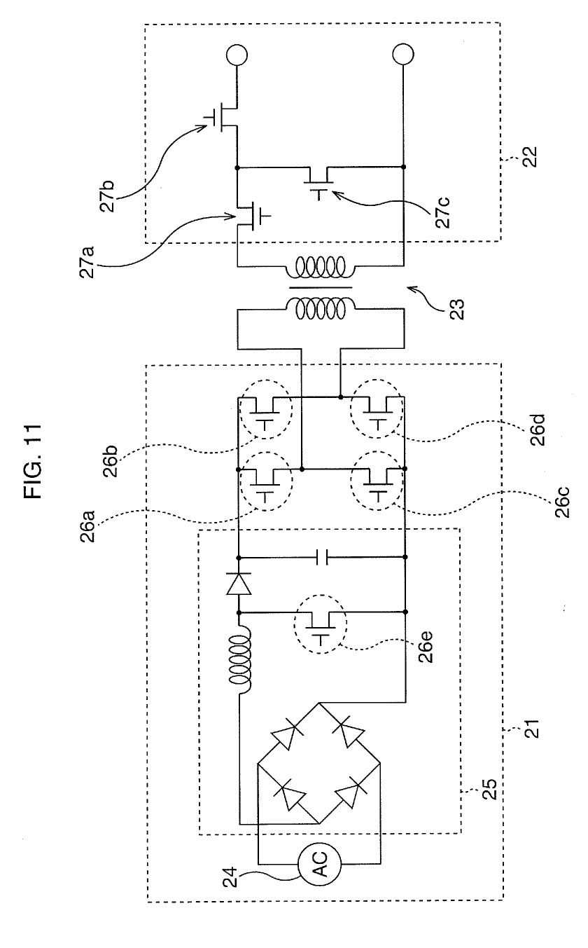

FIG. 11 is a connection diagram illustrating an overall configuration of the power supply of the third embodiment.

The power supply of this embodiment is composed of a high-voltage primary circuit 21 and a low-voltage secondary circuit 22, and a transformer 23 provided between the primary circuit 21 and the secondary circuit 22.

The primary circuit 21 is configured by an AC power source 24, a so-called bridge rectifier circuit 25, and a plurality of (four, in this case) switching elements 26a, 26b, 26c, 26d. The bridge rectifier circuit 25 has a switching element 26e.

The secondary circuit 32 is configured by a plurality of (three, in this case) switching elements 27a, 27b, 27c.

In this embodiment, the switching elements 26a, 26b, 26c, 26d, 26e in the primary circuit 21 are configured by any one type of the AlGaN/GaN-based HEMT selected from those in the first embodiment and the modified example thereof, and the second embodiment. On the other hand, the switching elements 27a, 27b, 27c in the secondary circuit 22 are configured by ordinary silicon-based MIS-FET.

In this embodiment, the highly reliable AlGaN/GaN-based HEMT featured by high voltage resistance and large output, and is thoroughly suppressed in degradation of device characteristics (chemical and/or physical changes) even under elevated operational voltage, is used for the high voltage circuit. In this way, a highly reliable power supply circuit for high power use may be implemented.

### Fourth Embodiment

This embodiment discloses a high-frequency amplifier equipped with any one type of AlGaN/GaN-based HEMT selected from those in the first embodiment and the modified example thereof, and the second embodiment.

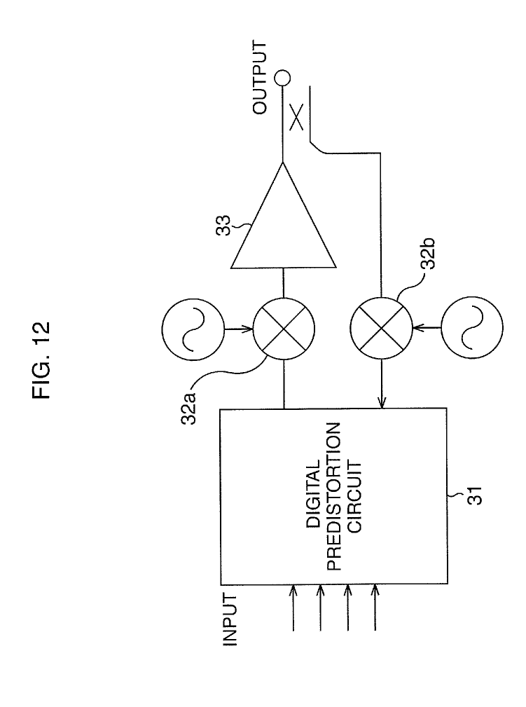

FIG. 12 is a connection diagram illustrating an overall configuration of high-frequency amplifier of the fourth embodiment.

The high-frequency amplifier of this embodiment is configured by a digital predistortion circuit 31, mixers 32a, 32b, and a power amplifier 33.

The digital predistortion circuit 31 compensates non-linear distortion in an input signal. The mixer 32a mixes the input signal having the non-linear distortion already compensated, with an AC signal. The power amplifier 33 amplifies the input signal having been mixed with the AC signal, and has any one type of AlGaN/GaN-based HEMT selected from first embodiment and the modified example thereof, and the second embodiment. In the configuration illustrated in FIG. 12, a signal on the output side is fed, typically by switching, to the digital predistortion circuit 31, after being mixed by the mixer 32b with an AC signal.

In this embodiment, the highly reliable AlGaN/GaN-based HEMT featured by high voltage resistance and large output, and is thoroughly suppressed in degradation of device characteristics (chemical and/or physical changes) even under elevated operational voltage, is used for the high-frequency amplifier. In this way, a highly reliable high-frequency amplifier for high voltage use may be implemented.

### Other Embodiments

While the first to fourth embodiments described in the above exemplified the AlGaN/GaN-based HEMT as the compound semiconductor device, other types of HEMT, other than the AlGaN/GaN-based HEMT, are adoptable to the compound semiconductor device.

### HEMT of Extra Example 1

This extra example discloses an InAlN/GaN-based HEMT as the compound semiconductor device.

InAlN and GaN are compound semiconductors which may be approximated in the lattice constant by tuning the composition. For the case where the InAlN/GaN-based HEMT is adopted to the aforementioned first embodiment and the modified example thereof, and the second to fourth embodiments, the channel layer will be made of i-GaN, the intermediate layer will be made of AlN, the donor layer will be made of n-InAlN, and the capping layer will be made of n-GaN. The two-dimensional electron gas in this configuration is mainly ascribable to spontaneous polarization of InAlN, with almost no contribution by Piezo polarization.

According to this extra example, there is implemented a highly reliable InAlN/GaN-based HEMT featured by high voltage resistance and large output, and is thoroughly suppressed in degradation of device characteristics (chemical and/or physical changes), even under elevated operational voltage, similarly to the aforementioned AlGaN/GaN-based HEMT.

### HEMT of Extra Example 2

This extra example discloses an InAlGaN/GaN-based HEMT as the compound semiconductor device.

When GaN and InAlGaN are compared, the latter has smaller lattice constant than that of the former. For the case where the InAlGaN/GaN-based HEMT is adopted to the aforementioned first embodiment and the modified example thereof, and the second to fourth embodiments, the channel layer will be made of i-GaN, the intermediate layer will be made of i-InAlGaN, the donor layer is made of n-InAlGaN, and the capping layer is made of n⁺-GaN.

According to this extra example, there is implemented a highly reliable InAlGaN/GaN-based HEMT featured by high voltage resistance and large output, and is thoroughly suppressed in degradation of device characteristics (chemical and/or physical changes), even under elevated operational voltage, similarly to the aforementioned AlGaN/GaN-based HEMT.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device comprising;
a compound semiconductor layer;
an insulating film which is composed of a single material and formed as a homogeneous film which covers the compound semiconductor layer, and has an opening formed therein; and
a gate which is formed over the compound semiconductor layer so as to fill the opening,
the compound semiconductor device further having an oxygen-containing protective component formed at one edge portion of the opening.

2. The compound semiconductor device according to claim 1, wherein the protective component is an oxide film formed so as to cover the one edge portion of the opening, between the gate and the insulating film.

3. The compound semiconductor device according to claim 2, wherein the oxide film has a tapered structure which is thinned towards the end thereof.

4. The compound semiconductor device according to claim 2, wherein the oxide film is formed so as to extend from the surface of the insulating film, covering the side face of the opening, to overlap a part of the bottom surface of the opening where the surface of the compound semiconductor layer exposes.

5. The compound semiconductor device according to claim 1, wherein the protective component is a local, surficial portion of the insulating film.

6. The compound semiconductor device according to claim 1, wherein the opening formed in the insulating film has a width narrower than the gate width, and
the protective component is positioned below the gate.

7. A method of manufacturing a compound semiconductor device comprising:
forming an insulating film which is composed of a single material and formed as a homogeneous film which covers the compound semiconductor layer, and has an opening formed therein; and
forming an oxygen-containing protective component at one edge portion of the opening formed in the insulating film; and
forming a gate over the compound semiconductor layer so as to fill the opening.

8. The method of manufacturing a compound semiconductor device according to claim 7, wherein in the step of forming the protective component, an oxide film is formed so as to cover an edge portion of the opening to thereby give the protective component.

9. The method of manufacturing a compound semiconductor device according to claim 8, wherein the oxide film is formed so as to be thinned towards the end thereof.

10. The method of manufacturing a compound semiconductor device according to claim 8, wherein the oxide film is formed so as to extend from the surface of the insulating film, covering the side face of the opening, to overlap a part of the bottom surface of the opening where the surface of the compound semiconductor layer exposes.

11. The method of manufacturing a compound semiconductor device according to claim 7, wherein in the step of forming the protective component, oxygen is introduced only into the surficial portion of one edge portion of the insulating film, so as to make the surficial portion as the protective component.

12. The method of manufacturing a compound semiconductor device according to claim 7, wherein the opening is formed in the insulating film while adjusting the width thereof narrower than the gate width, and
the protective component is formed so as to be positioned below the gate.

13. A power supply circuit comprising a transformer; and a high voltage circuit and a low voltage circuit provided while placing the transformer in between,
the high voltage circuit having a transistor,
the transistor having:
a compound semiconductor layer;
an insulating film composed of a single material and formed as a homogeneous film which covers the compound semiconductor layer, and has an opening formed therein; and
a gate which is formed over the compound semiconductor layer so as to fill the opening,
the transistor further having an oxygen-containing protective component formed at one edge portion of the opening.

14. A high-frequency amplifier which receives high-frequency voltage and gives an amplified output,
the high-frequency amplifier having a transistor,
the transistor having:
a compound semiconductor layer;
an insulating film composed of a single material and formed as a homogeneous film which covers the compound semiconductor layer, and has an opening formed therein; and
a gate which is formed over the compound semiconductor layer so as to fill the opening,
the transistor further having an oxygen-containing protective component formed at one edge portion of the opening.
